(19) United States
(12) Patent Application Publication
(10) Pub. No.: US 2012/0017433 A1
(43) Pub. Date: Jan. 26, 2012

(54) METHOD OF MANUFACTURING TOUCH SCREEN

(75) Inventors: IL Kwon Chung, Gyunggi-do (KR); Jong Young Lee, Gyunggi-do (KR)

(73) Assignee: SAMSUNG ELECTRO-MECHANICS CO., LTD., Gyunggi-do (KR)

(21) Appl. No.: 12/941,858

(22) Filed: Nov. 8, 2010

(30) Foreign Application Priority Data
Jul. 20, 2010 (KR) 1020100070064

(51) Int. Cl. H05K 13/00

(52) U.S. Cl. 29/829

(57) ABSTRACT

Disclosed herein is a method of manufacturing a touch screen, including: (A) preparing a transparent substrate; (B) forming a patterned transparent electrode including a conductive polymer on the transparent substrate and allowing patterns of the transparent electrode in different columns to be connected by a connection part; and (C) removing the connection part of the transparent electrode. The method of manufacturing a touch screen forms the transparent electrode so that the patterns in different columns are definitely spaced apart from each other to accurately detect touched positions.

### CROSS REFERENCE TO RELATED APPLICATION

This application claims the benefit of Korean Patent Application No. 10-2010-0070064, filed on Jul. 20, 2010, entitled “Method Of Manufacturing Touch Screen” which is hereby incorporated by reference in its entirety into this application.

### BACKGROUND OF THE INVENTION

1. Technical Field

The present invention relates to a method of manufacturing a touch screen.

2. Description of the Related Art

With the continuous development in the electronic technology and the information technology fields, the relative importance of electronic devices is constantly increasing in everyday life, including a work environment. In particular, as electronic technology continuously develops, personal computers and portable transmitters etc. process texts and graphics, using a variety of input devices, such as a keyboard, a mouse, a digitizer, etc. These input devices, however, have been developed in consideration of the expanding usage of personal computers, such that they are difficult to be applied to portable devices that are recently reduced in size and thickness. Therefore, touch screens are on the rise as an input device appropriate for portable devices.

Touch screens, devices generally installed in display devices to detect positions on the screen touched by a user and control electronic devices, using information on the detected contact position as input information, in addition to controlling the screen of the display, have various advantages of being simply operated with minimal malfunction in a small space and very compatible with IT devices.

Meanwhile, the touch screen is classifiable as a resistive type, a capacitive type, an electromagnetic type, a surface acoustic wave (SAW) type, an infrared type, and so on. Among others, resistive and capacitive types are prevalently used in consideration of the functions and economic costs. Researches on a capacitive touch screen capable of easily implementing a multi-touch, while having excellent durability, have been conducted.

A capacitive touch screen generally includes a transparent substrate and a transparent electrode formed on the transparent substrate. At this time, the transparent electrode may have a pattern configured of several columns, wherein the pattern in different columns may be spaced apart from each other by about 100 μm.

However, the transparent electrode of the touch screen according to the prior art has a difficulty in forming the patterns in different columns to be spaced apart from each other by about 100 μm. More specifically, when the transparent electrode is formed by printing a conductive polymer, the patterns in different columns are undesirably connected due to the diffusion of the conductive polymer. In order to solve this problem, even though there have been attempts to control the interval between the patterns, it has been difficult to be technically implemented due to the narrow interval of about 100 μm between the patterns in different columns. In addition, when a touch screen is manufactured neglecting that the patterns in different columns are undesirably connected, the patterns in different columns are electrically connected, such that touched positions are not accurately measured, for example, sensing that ‘position ‘B’ is touched even though position ‘A’ is touched.

### SUMMARY OF THE INVENTION

The present invention has been made in an effort to provide a method of manufacturing a touch screen that forms a transparent electrode so that patterns in different columns are definitely spaced apart from each other to accurately measure touched positions.

A method of manufacturing a touch screen according to a preferred embodiment of the present invention includes: (A) preparing a transparent substrate; (B) forming a patterned transparent electrode including a conductive polymer on the transparent substrate and allowing patterns of the transparent electrode in different columns to be connected by a connection part; and (C) removing the connection part of the transparent electrode.

At this time, the transparent electrode includes a sensing unit sensing touch signals, and a bridge connecting the sensing units in the same column.

At step (B), the sensing unit has a diamond shape in which it is connected to a sensing unit in a different column through the connection part, and at step (C), the sensing unit has a hexagonal shape or a pentagonal shape in which the connection part is removed.

At step (C), the connection part of the transparent electrode is removed by a laser method or an etching method.

At step (B), the transparent electrode is formed by a printing method.

The method further includes (D) forming an adhesive layer on the transparent substrate on which the transparent electrode is formed and bonding it to a window plate.

### BRIEF DESCRIPTION OF THE DRAWINGS

FIGS. 1 to 4 are process perspective views for explaining a method of manufacturing a touch screen according to a preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Meanwhile, in the use of terms in the present invention, “contact input” means both “contact” and “approximation”. “Contact” means the case being completely contacted, and “approximation” means the case being very close even though not being completely contacted.

Hereinafter, preferred embodiments of the present invention will be described in detail with reference to the accompanying drawings.

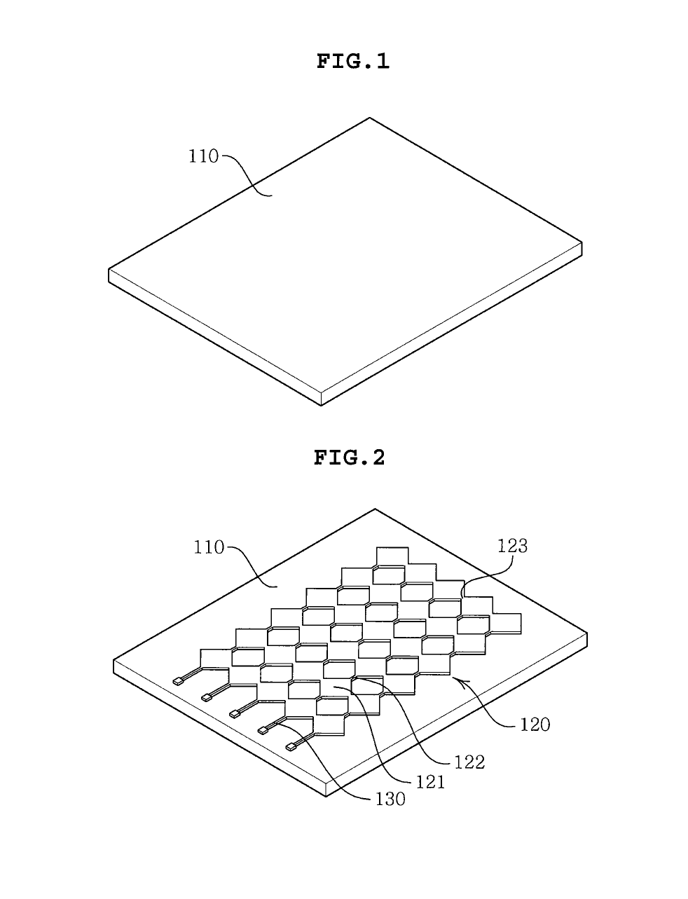

FIGS. 1 to 4 are process perspective views for explaining a method of manufacturing a touch screen 100 according to a preferred embodiment of the present invention. Hereinafter, the touch screen 100 according to the present embodiment will be described with reference to these figures. The present embodiment will mainly describe a capacitive touch screen 100 in which transparent electrodes 120 are formed on both surfaces of a transparent substrate 110. However, it is previously defined that the present invention is not limited thereto but includes a capacitive touch screen in which the transparent electrode 120 is formed on one surface of the transparent substrate 110, or a capacitive touch screen in which two transparent substrates 110 on which the transparent electrodes 120 are formed are bonded using an adhesive layer.

First, as shown in FIG. 1, a transparent substrate 110 is prepared.

In this case, it is preferable that the transparent substrate 110 is made of a transparent material so that an image from a display (not shown) installed at the lower portion of the touch screen 100 can be clearly transferred to a user. As such a material, the transparent substrate 110 may, for example, be made of polyethyleneterephthalate (PET), polycarbonate (PC), polymethylmetacrylate (PMMA), polyethylenenaphthalenedicarboxylate (PEN), polyethersulfone (PES) or cyclic olefin copolymer (COC). Besides, glass or tempered glass may be generally used.

In addition, the transparent electrode 120 is formed on the transparent substrate 110, such that it is preferable to perform a high-frequency treatment or a primer treatment thereon in order to improve the adhesion with the transparent electrode 120.

Next, as shown in FIG. 2, transparent electrodes 120 are formed on both surfaces of the transparent substrate 110.

In this configuration, the transparent electrode 120 is a member to sense change in capacitance while being input by contact. The transparent electrode 120 formed on one surface of the transparent substrate 110 may form an X-axis pattern and a transparent electrode (not shown) formed on the other surface thereof may form a Y-axis pattern. More specifically, the transparent electrode 120 senses the change in capacitance from the contact input of a specific object, such as a user's body or a stylus pen, etc. and transmits the change to a controller (not shown), and then the controller (not shown) recognizes the coordinates of the pressed position, thereby implementing desired operations. More specifically, when high frequency is diffused throughout the transparent electrodes 120 by receiving voltage through the electrodes 130 and then the contact input is applied by a human body or the like, a predetermined change in capacitance occurs while the transparent electrodes 120 function as electrodes and a window plate 140 and/or the transparent substrate 110 functions as dielectrics, and the controller (not shown) can recognize the contact position or whether there is contact, etc., by detecting the changed waveform.

In this case, it is preferable that the transparent electrode 120 is made of a conductive material so as to sense the change in capacitance. In addition, it is preferable that the transparent electrode 120 is made of a transparent material, since it is formed over the transparent substrate 110. As such a material, the transparent electrode 120 may, for example, be made of conductive polymer containing poly-3,4-ethylenedioxythiophene/polystyrenesulfonate (PEDOT/PSS), polyaniline alone or a mixture thereof.

Meanwhile, the transparent electrode 120 may be formed on the transparent substrate 110 by a printing method, for example, a silk screen printing method, an inkjet printing method, a gravure printing method, an offset printing method, or the like. For example, when the transparent electrode 120 is formed by a silk screen printing method, an ink paste made of a conductive polymer is put on a screen in a state in which the screen is tightly pulled by strong tension and then the paste is pushed out to the surface of the transparent substrate 110 through meshes of the screen to be transferred by pushing down and moving a squeegee. In this case, the pattern of the screen may be transferred to the transparent electrode 120.

In addition, the transparent electrode 120 may be configured of patterns in various shapes, such as a bar shape, a hexagonal shape, a diamond shape, a triangular shape, or the like. The present embodiment will describe a case in which the transparent electrode 120 is formed in diamond-shaped patterns by way of example. Herein, the pattern of the transparent electrode 120 may have a shape in which a diamond-shaped sensing unit 121 sensing touch signals is connected to a bridge 122. More specifically, two apexes of the sensing unit 121, facing each other, are connected to the bridge 122, such that the sensing unit 121 may be connected to another sensing unit 121. In addition, the transparent electrode 120 may be formed to be connected to the sensing unit 121 in another column through a connection part 123. The connection part 123 is a portion to be subsequently removed. The connection part 123 may be generated but not intended, due to the diffusion property of the conductive polymer even though the patterns in different columns are formed to be spaced apart from each other. In other words, even though an opening portion of the screen is formed to be spaced apart when the transparent electrode 120 including the conductive polymer is formed by a printing method, two apexes of the sensing units 121 in different columns may be formed to be connected to each other due to the diffusion of the conductive polymer. Alternatively, the interval between the sensing units 121 in different columns is about 100 μm and thus it is difficult to control the interval, such that the patterns in different columns may be intentionally connected to each other by the connection part 123.

Meanwhile, the present embodiment describes the case in which the transparent electrodes 120 are formed on both surfaces of the transparent substrate 110 to form an X-axis pattern and a Y-axis pattern, respectively. However, when the transparent electrode 120 is formed on only one surface of the transparent substrate 110, the X-axis patterns and the Y-axis patterns are connected through the bridges and an insulating layer is formed between the bridges, such that they can be electrically insulated.

In addition, at this stage, an electrode 130 applying voltage to the transparent electrode 120 may be formed. It is preferable that the electrode 130 is made of a material having excellent electrical conductivity so as to supply voltage to the transparent electrode 120, such as silver (Ag) paste or a material composed of organic silver. In addition, the electrode 130 may be formed on the transparent substrate 110 or the transparent electrode 120 by a printing method or the like.

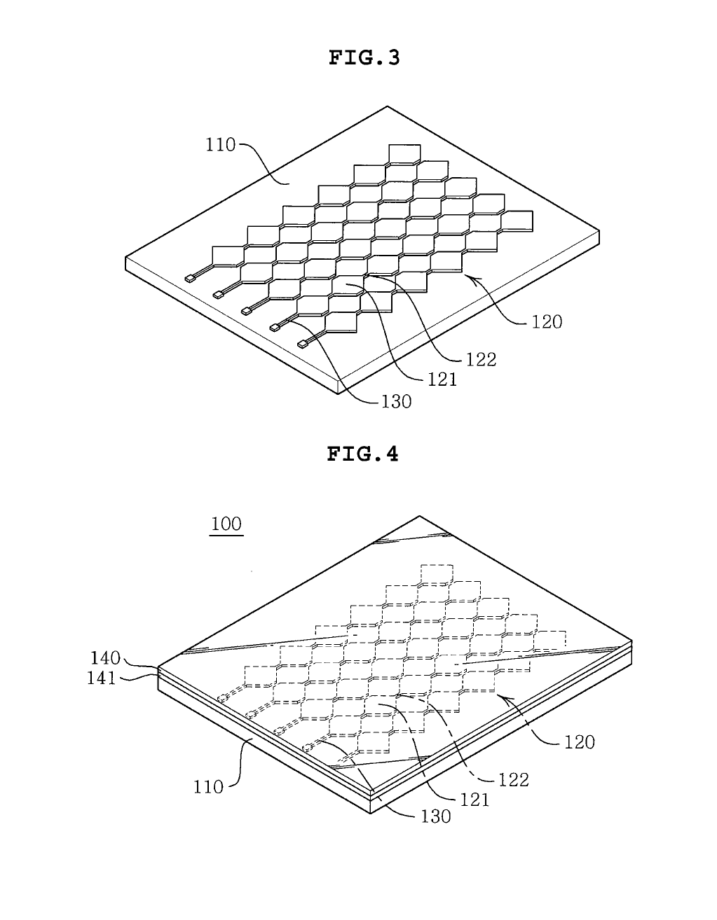

Next, as shown in FIG. 3, the connection part 123 of the transparent electrode 120 is removed.

In this case, when the connection part 123 is formed, the patterns in different columns are shorted and thus cause difficulty in accurately measuring touched positions. Therefore, it is preferable that the connection part 123 is removed. The connection part 123 may be removed by, for example, performing laser etching or applying an etching solution.

Therefore, the original sensing unit 121 having a diamond shape may be changed to have a hexagonal shape as the two apexes thereof facing each other are cut away. In this case, the sensing unit 121 at the edge of the pattern may be changed to have a pentagonal shape as only one apex is cut away. In addition, as the connection part 123 is removed, the patterns in different columns each may independently transfer signals. In addition, the patterns in different columns are spaced apart from each other, thereby making it possible to accurately measure touched points. In addition, the connection part 123 is removed by a laser method, an etching method or the like, that is relatively simple, thereby making it possible to reduce process time and process costs.

Next, as shown in FIG. 4, an adhesive layer 141 is formed on the transparent substrate 110 on which the transparent electrode 120 is formed and is bonded to a window plate 140.

In this case, the window plate 140, which is a part receiving an input from a specific object, such as a user's body or a stylus pen, maintains the external appearance of the input unit of the touch screen 100. Therefore, it is preferable that the window plate 140 is made of a transparent material for a user to be able to see a display well, having large durability so as to sufficiently protect the touch screen 100 from the external force, for example, polyethylene terephthalate (PET) or glass.

In addition, the adhesive layer 141 may be formed over the transparent substrate 110 and should be transparent so that a user can see a display. To this end, the adhesive layer 141 may be formed of an optically clear adhesive (OCA).

Meanwhile, a flexible printed cable (not shown) connecting the electrode 130 to an external substrate may further be formed before the window plate 140 is bonded.

The touch screen 100 according to a preferred embodiment of the present invention shown in FIG. 4 is manufactured according to the manufacturing processes as described above.

According to the present invention, the method of manufacturing a touch screen forms the patterns of the transparent electrode in different columns to be connected and then removes the connection part to definitely space apart the patterns in different columns, thereby making it possible to accurately measure the touched points.

In addition, according to the present invention, no complicated control is needed in order to space apart the patterns of the transparent electrode in different columns and the connection part is removed by a laser method or an etching method, that is relatively simple, thereby making it possible to reduce process time and process costs.

Although the preferred embodiments of the present invention have been disclosed for illustrative purposes, they are for specifically explaining the present invention and thus the method of manufacturing a touch screen according to the present invention is not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A method of manufacturing a touch screen, comprising:
(A) preparing a transparent substrate;
(B) forming a patterned transparent electrode including a conductive polymer on the transparent substrate and allowing patterns of the transparent electrode in different columns to be connected by a connection part; and
(C) removing the connection part of the transparent electrode.

2. The method of manufacturing a touch screen as set forth in claim 1, wherein the transparent electrode includes:
a sensing unit sensing touch signals; and
a bridge connecting the sensing units in the same column.

3. The method of manufacturing a touch screen as set forth in claim 2, wherein at step (B), the sensing unit has a diamond shape in which it is connected to a sensing unit in a different column through the connection part, and
at step (C), the sensing unit has a hexagonal shape or a pentagonal shape in which the connection part is removed.

4. The method of manufacturing a touch screen as set forth in claim 1, wherein at step (C), the connection part of the transparent electrode is removed by a laser method or an etching method.

5. The method of manufacturing a touch screen as set forth in claim 1, wherein at step (B), the transparent electrode is formed by a printing method.

6. The method of manufacturing a touch screen as set forth in claim 1, further comprising (D) forming an adhesive layer on the transparent substrate on which the transparent electrode is formed and bonding it to a window plate.
